(19) United States
(12) Patent Application Publication
(10) Pub. No.: US 2009/0184420 A1
(43) Pub. Date: Jul. 23, 2009

(54) Post bump and method of forming the same

(75) Inventors: Jin-Won Choi, Seoul (KR); Chang-Sup Ryu, Yongin-si (KR); Seung-Hyun Cho, Seoul (KR); Seung-Wan Kim, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTROMECHANICS CO., LTD., Suwon (KR)

(21) Appl. No.: 12/213,466

(22) Filed: Jun. 19, 2008

(30) Foreign Application Priority Data
Jan. 22, 2008 (KR) 10-2008-0006487

(51) Int. Cl. H01L 23/488; H01L 21/44; H05K 3/00; H05K 1/00

(52) U.S. Cl. 257/738; 438/613; 29/846; 174/267

(57) ABSTRACT

A post bump and a method of forming the post bump are disclosed. The method of forming the post bump can include: forming a resist layer, in which an aperture is formed in correspondence to a position of an electrode pad, over a substrate, on which the electrode pad is formed; forming a metal post by filling a part of the aperture with a metallic material; filling a remaining part of the aperture with solder; reflowing the solder by applying heat; and removing the resist layer. This method can be utilized to prevent deviations in the plated solder and prevent the unnecessary flowing of the solder over the sides of the metal post during reflowing, so that the amount of solder used can be minimized.

### CROSS-REFERENCE TO RELATED APPLICATIONS

This application claims the benefit of Korean Patent Application No. 10-2008-0006487 filed with the Korean Intellectual Property Office on Jan. 22, 2008, the disclosure of which is incorporated herein by reference in its entirety.

### BACKGROUND

1. Technical Field

The present invention relates to a post bump and a method of forming the post bump.

2. Description of the Related Art

Flip chip packaging is a technique of bonding and packaging an electronic component in a circuit board, where the component, such as a semiconductor chip, and the circuit board are attached by fusing solder bumps onto the semiconductor chip or the circuit board, instead of using additional connection structures such as wires.

In accordance with current requirements for high-speed, high-capacity data processing, as well as for smaller, lighter, and thinner electronic products, components are trending towards smaller bump pitch. Because of this trend, however, flip chip packaging is liable to provide lower reliability in the bump connections between a circuit board and a semiconductor chip. Attempts to improve the reliability of such bump connections have led to the use of solder bumps having a post bump structure.

FIG. 1 through FIG. 7 are cross sectional views representing a flow diagram for a method of forming post bumps according to the related art, and FIG. 8 is a cross sectional view illustrating the bonding between post bumps according to the related art. A method of forming post bumps according to the related art may include, first, forming a seed layer 108 over a semiconductor chip 102 on which electrode pads 104 are formed, as illustrated in FIG. 1 and FIG. 2. A solder resist 106, which is an insulating material, may be formed over the surface of the semiconductor chip 102 where the electrode pads 104 are formed. Next, as illustrated in FIG. 3, a photosensitive dry film 109 may be stacked over the semiconductor chip 102 on which the electrode pads 104 are formed, and portions corresponding to the positions of the electrode pads 104 may be uncovered to form apertures 110. Next, as illustrated in FIG. 4, electroplating may be performed using the seed layer 108 as an electrode, to partially fill the apertures 110 with copper and form copper posts 112. Next, as illustrated in FIG. 5, electroplating may be performed using the seed layer 108 as an electrode, to fill the remaining parts of the apertures 110 with solder 114. Next, as illustrated in FIG. 6, the dry film 109 remaining on the semiconductor chip 102 may be removed, and the seed layer 108 exposed to the outside may be removed. Next, as illustrated in FIG. 7, the solder 114 formed on the copper posts 112 may be reflowed, to form spherical solder shapes.

With this method of forming post bumps according to the related art, however, the operation of filling the remaining parts of the apertures 110 with solder 114 can result in uneven amounts of plating, due to the potential difference that may occur during the electroplating.

Also, when reflowing the solder 114 plated over the copper posts 112, the solder 114 may flow over the sides of the copper posts 112. As such, the solder 114 may have to be applied taking into account the amount of solder 114 flowing over the sides of the copper posts 112, in addition to the minimum amount of solder 114 required for the flip chip bonding.

Furthermore, as illustrated in FIG. 8, the uneven amounts of plating can lead to uneven shapes (see FIG. 7) in the spherically shaped solder 114 formed by reflowing, so that when bonding the semiconductor chip 102 with a circuit board 116, bridges may be formed between adjacent bumps, or bonding defects may occur due to insufficient amounts of solder.

### SUMMARY

An aspect of the invention provides a post bump and a method of forming the post bump, which prevent deviations in the plated solder and prevent the unnecessary flowing of the solder over the sides of the metal post during reflowing.

Another aspect of the invention provides a method of forming a post bump that includes: forming a resist layer, in which an aperture is formed in correspondence to a position of an electrode pad, over a substrate, on which the electrode pad is formed; forming a metal post by filling a part of the aperture with a metallic material; filling a remaining part of the aperture with solder; reflowing the solder by applying heat; and removing the resist layer.

The operation of forming the resist layer can include stacking a photosensitive film layer over the substrate on which the electrode pads are formed, and forming the aperture by removing a portion of the photosensitive film layer by way of selective exposure and development such that an area corresponding to the position of the electrode pad is uncovered.

The removing of the resist layer can include an operation of removing the photosensitive film layer remaining on the substrate.

In certain implementations, the method can further include forming a seed layer over the substrate by depositing a conductive material, before the forming of the resist layer. In such cases, the forming of the metal post can include performing electroplating, using the seed layer as an electrode.

In certain implementations, the method can further include, after the removing of the resist layer, removing the seed layer exposed to the outside.

The operation of filling with the solder may include forcing the solder into the remaining part of the aperture by squeegeeing.

A dry film that is thermally resistant to the reflowing can be used for the photosensitive film layer.

The substrate can be any one of a circuit board, a semiconductor wafer, and an electronic component.

The solder can be any one of a Sn—Pb solder, a Sn—Ag solder, and a Sn—Ag—Cu solder.

Yet another aspect of the invention provides a post bump formed over an electrode pad of a substrate for electrically connecting to an external device. The post bump includes a metal post formed over the electrode pad, and a solder formed over the metal post and shaped as a dome, where the dome may occupy a space defined by imaginary lines extending from a perimeter of the metal post along an axial direction of the metal post.

Here, the substrate can be any one of a circuit board, a semiconductor wafer, and an electronic component.

The solder can be any one of a Sn—Pb solder, a Sn—Ag solder, and a Sn—Ag—Cu solder.

Additional aspects and advantages of the present invention will be set forth in part in the description which follows, and in part will be obvious from the description, or may be learned by practice of the invention.

### BRIEF DESCRIPTION OF THE DRAWINGS

FIG. 1, FIG. 2, FIG. 3, FIG. 4, FIG. 5, FIG. 6, and FIG. 7 are cross sectional views representing a flow diagram for a method of forming post bumps according to the related art.

FIG. 8 is a cross sectional view illustrating the bonding between post bumps according to the related art.

FIG. 9 is a flowchart illustrating a method of forming post bumps according to a first disclosed embodiment of the invention.

FIG. 10, FIG. 11, FIG. 12, FIG. 13, FIG. 14, FIG. 15, and FIG. 16 are cross sectional views representing a flow diagram for a method of forming post bumps according to the first disclosed embodiment of the invention.

FIG. 17 is a perspective view of a post bump according to a second disclosed embodiment of the invention.

FIG. 18 is a perspective view of a post bump according to a third disclosed embodiment of the invention.

FIG. 19 is a perspective view of a post bump according to a fourth disclosed embodiment of the invention.

FIG. 20 is a cross sectional view illustrating the bonding between post bumps according to the second disclosed embodiment of the invention.

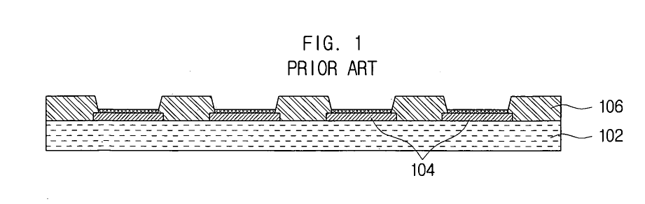

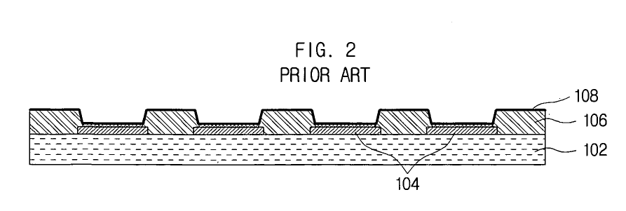

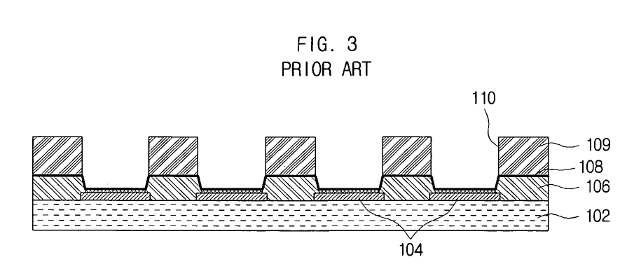

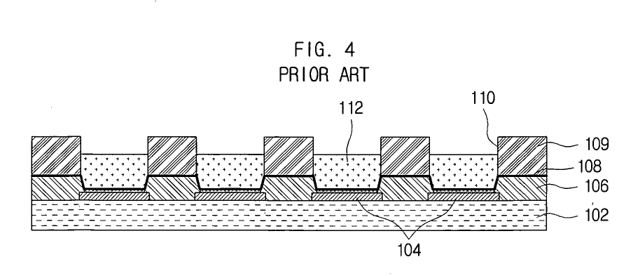

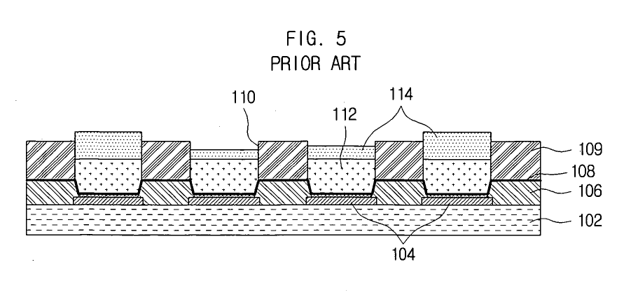

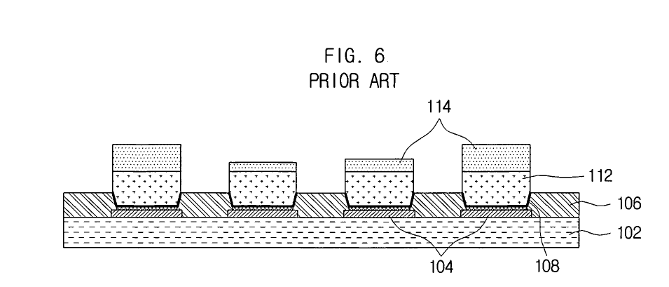

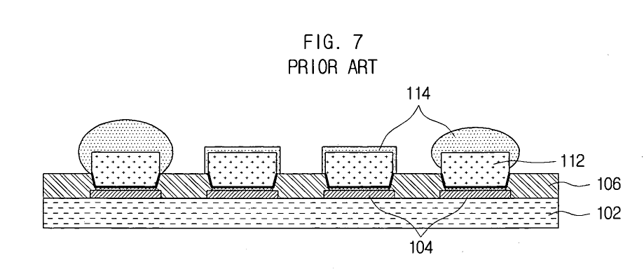

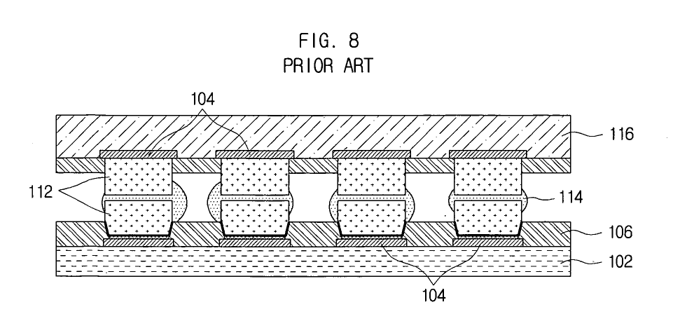

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

The post bump and method of forming the post bump according to certain embodiments of the invention will be described below in more detail with reference to the accompanying drawings. Those elements that are the same or are in correspondence are rendered the same reference numeral regardless of the figure number, and redundant explanations are omitted.

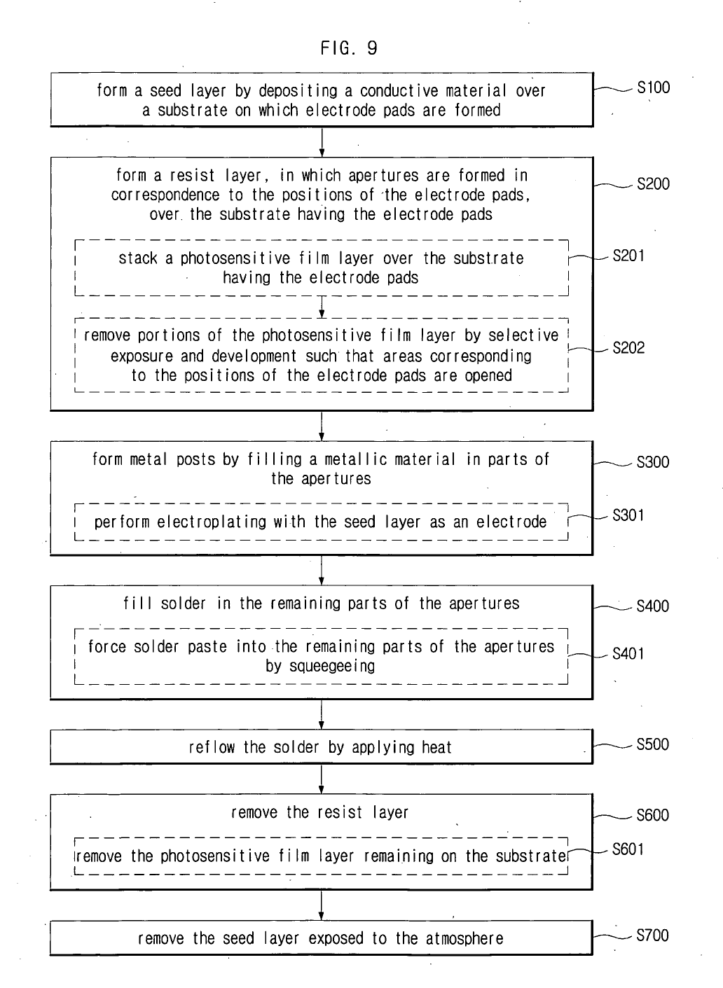

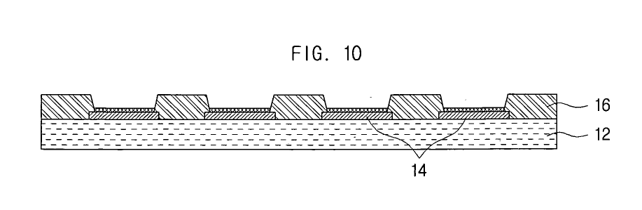

FIG. 9 is a flowchart illustrating a method of forming post bumps according to a first disclosed embodiment of the invention, and FIG. 10 through FIG. 16 are cross sectional views representing a flow diagram for a method of forming post bumps according to the first disclosed embodiment of the invention. In FIGS. 10 to 16, there are illustrated a substrate 12, electrode pads 14, a solder resist 16, a seed layer 18, a photosensitive film layer 20, apertures 22, metal posts 24, solder paste 26, a squeegee 28, and solder 30.

A method of forming post bumps according to this embodiment can include forming a resist layer over a substrate 12, where electrode pads 14 are formed on the substrate 12 and apertures 22 are formed in the resist layer in correspondence to the positions of the electrode pads 14, forming metal posts 24 by filling parts of the apertures 22 with a metallic material, filling the remaining parts of the apertures 22 with solder 30, reflowing the solder 30 by applying heat, and removing the resist layer. This method prevents unnecessary flowing of the solder 30 over the sides of the metal posts during reflowing, to minimize the use of solder 30 and improve the reliability of the connections between an electronic component and a circuit board.

In the method of forming post bumps according to this embodiment, first, as illustrated in FIG. 10 and FIG. 11, a conductive material can be deposited over the substrate 12 on which the electrode pads 14 are formed, to form a seed layer 18 (S100). The seed layer 18 may later serve as an electrode when electroplating is performed.

A substrate 12 refers to a flat base, and can be any one of a circuit board, a semiconductor wafer, and an electronic component. The electrode pads can provide electrical connection between the substrate and an external device, and can be exposed to the outside by the solder resist 16.

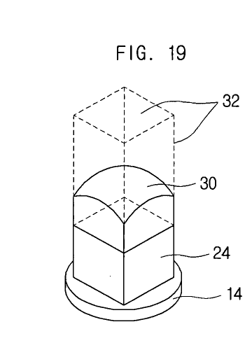

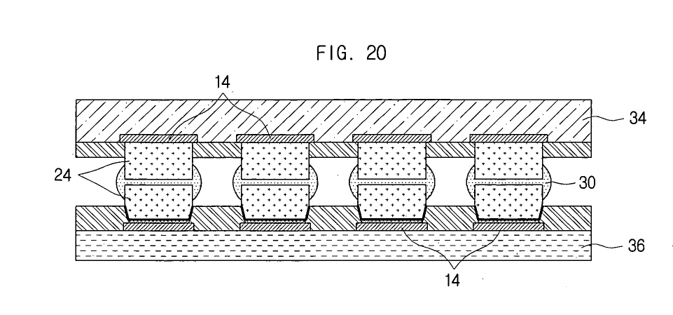

The post bumps formed according to this embodiment can be formed over the electrode pads 14 of an electronic component or a circuit board for use in flip chip bonding. For example, it is possible to form the post bumps over the electrode pads 14 of an electronic component and then bond the electronic component with the post bumps to a circuit board, or conversely, to form the post bumps over the electrode pads 14 of the circuit board and then bond the component to the circuit board. Furthermore, as illustrated in FIG. 20, it is also possible bond the component with the circuit board after forming post bumps on both the electrode pads 14 of the component and on the electrode pads 14 of the circuit board. When manufacturing a wafer level package, the post bumps can be formed according to this embodiment over electrode pads 14 formed on a wafer.

Next, as illustrated in FIG. 12, a resist layer that has apertures 22 formed in correspondence with the positions of the electrode pads 14 can be formed over the substrate 12 on which the electrode pads 14 are formed (S200).

This particular embodiment provides a method of forming the resist layer using a photosensitive film layer 20 that is sensitive to ultraviolet rays.

That is, a photosensitive film layer 20 can be stacked over the substrate 12 on which the electrode pads 14 are formed (S201), and portions of the photosensitive film layer 20 can be removed by selective exposure and development, such that areas corresponding to the positions of the electrode pads 14 are uncovered, to form the apertures 22 (S202).

A dry film or a UV-setting photosensitive liquid can be used for the photosensitive film layer 20. The dry film can be attached to the substrate 12 using a laminator, while the photosensitive liquid can be coated onto the substrate 12 and dried to form the photosensitive film layer 20.

When the photosensitive film layer 20 is irradiated with ultraviolet rays, portions of the photosensitive film layer 20 outside the shielded areas may be exposed to the ultraviolet rays and may be cured as a result of polymerization, while the shielded areas may remain unchanged. As such, by shielding the areas corresponding to the positions of the electrode pads 14, irradiating ultraviolet rays, and developing, apertures 22 can be formed in the areas corresponding to the positions of the electrode pads 14.

The photosensitive, film layer 20 can also be a dry film that is thermally resistant to the subsequent reflowing process.

Next, as illustrated in FIG. 13, a metallic material can be filled in parts of the apertures 22 to form metal posts 24 (S300). In this particular embodiment, the apertures 22 may be partially filled with a metallic material by performing electroplating using the seed layer 18 formed in a previous process as an electrode (S301), to form the metal posts 24. The metallic material may be a conductive material, which allows the flow of electricity. This particular embodiment provides a method of forming the metal posts 24 by electroplating copper (Cu), which can be attached to the electrode pads 14 in a stable manner. The height to which the metal posts 24 are formed may be adjusted according to the height of the bumps required for bonding.

Next, as illustrated in FIG. 14, the remaining parts of the apertures 22 can be filled in with solder 30 (S400). The solder 30 may temporarily melt during the reflowing to allow flip chip bonding. In this particular embodiment, the filling in of the solder 30 into the remaining parts of the apertures 22 can be achieved by forcing solder paste 26 into the remaining parts of the apertures 22 using squeegeeing (S401). That is, the upper portion of the photosensitive film layer 20 can be coated with a solder paste 26, which can be pushed using a squeegee 28, so that the solder paste 26 may be forced into the apertures 22 of the photosensitive film layer 20. By forcing the solder paste 26 in using a squeegeeing method, the apertures 22 can be evenly filled with the solder paste 26. The evenly filled solder 30 can be formed into a uniform dome shape during the subsequent reflowing, so that the connections provided by flip chip bonding can be improved in reliability.

Of course, it is also possible to fill the solder 30 in the remaining parts of the apertures 22 by performing electroplating using the seed layer 18 as an electrode.

The solder 30 can be any one selected from a group consisting of Sn—Pb solder, Sn—Ag solder, and Sn—Ag—Cu solder. Using Sn—Ag solder or Sn—Ag—Cu solder can reduce the use of lead.

Next, as illustrated in FIG. 15, the solder 30 can be heated for reflowing (S500). Since the solder 30 has a lower fusing point than that of the metal posts 24, the solder 30 can be formed by the reflowing process into a dome-like shape. In this embodiment, heat may be applied to the solder 30 for reflowing before removing the photosensitive film layer 20, whereby the solder 30 may be prevented from flowing over the sides of the metal posts 24, and amounts of unnecessary solder 30 may be reduced. The solder 30 evenly filled in the apertures 22 in a previous operation can be formed by the reflowing process into a dome shape. The even dome-shaped solder 30 may entail a substantially uniform volume, and may therefore improve the reliability of connections in flip chip bonding. In addition, it may be easier to control the processes.

Thus, by sequentially filling a metallic material and solder 30 into the apertures 22 formed in the photosensitive film layer 20, and afterwards applying heat to the solder 30 for reflowing without the photosensitive film layer 20 removed, the solder 30 can be formed into a dome-like shape that occupies a space defined by imaginary lines 32 extending from a perimeter of each metal post 24 along an axial direction of the metal post 24 (for example, a space formed by the remaining part of the aperture 22). During reflowing, the solder 30 can be formed into a dome shape that does not flow over the sides of the metal posts 24 other than the top surface, so that the amount of solder 30 required for bonding may readily be controlled.

When applying heat to the solder 30 for reflowing, a dry film capable of thermally resisting the reflowing may be used for the photosensitive film layer 20, in order to prevent deformations in the photosensitive film layer 20.

Next, as illustrated in FIG. 16, the resist layer can be removed (S600). If the photosensitive film layer 20 is used for the resist layer, the photosensitive film layer 20 remaining on the substrate 12 can be removed (S601). Then, the seed layer 18 exposed to the atmosphere can be removed (S700). When the solder 30 is cured, following the forming of the solder 30 into a dome-like shape by reflowing, the photosensitive film layer 20 remaining on the substrate 12 and the seed layer 18 exposed to the atmosphere may be removed.

As set forth above, when post bumps are formed according to this embodiment over multiple electrode pads 14, the dome-shaped solder 30 may maintain a uniform shape and volume, to improve the connections in flip chip bonding and facilitate the control of the processes.

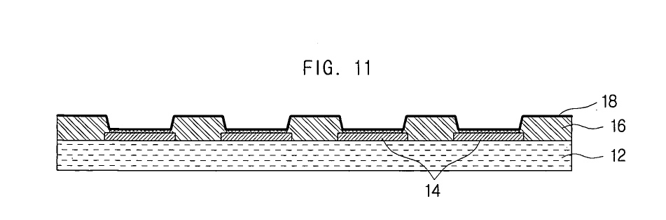

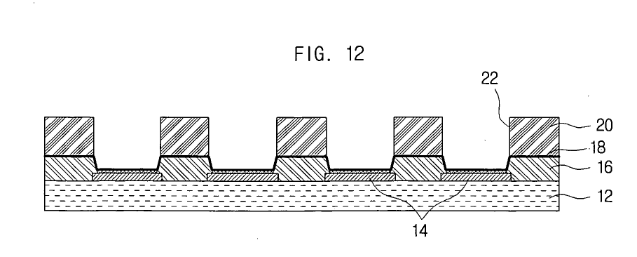

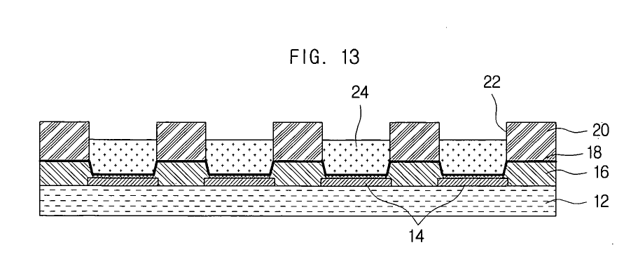

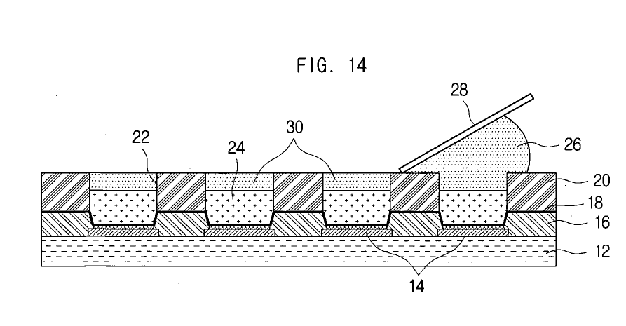

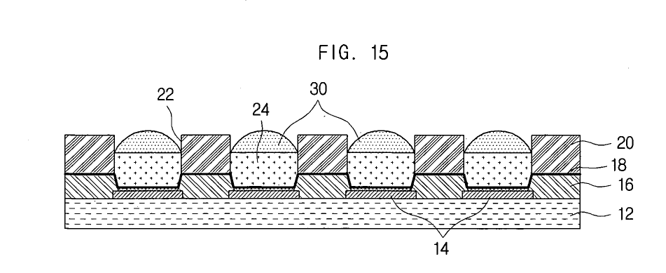

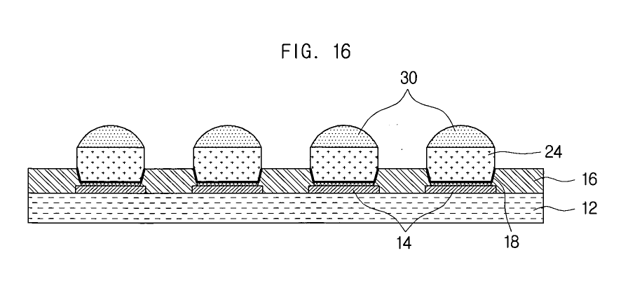

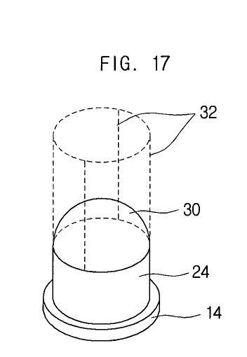

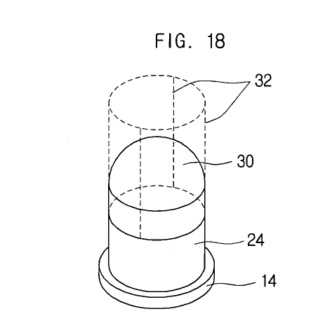

FIG. 17 is a perspective view of a post bump according to a second disclosed embodiment of the invention, FIG. 18 is a perspective view of a post bump according to a third disclosed embodiment of the invention, and FIG. 19 is a perspective view of a post bump according to a fourth disclosed embodiment of the invention. In each of FIGS. 17 to 19, there are illustrated an electrode pad 14, a metal post 24, solder 30, and imaginary lines 32.

A post bump based on this embodiment can be a bump formed over an electrode pad 14 of a substrate for providing an electrical connection to an external device. The post bump, can include a metal post 24, which may be formed over the electrode pad 14, and solder 30 shaped as a dome, which may occupy a space defined by imaginary lines 32 extending from the perimeter of the metal post 24 along the axial direction of the metal post 24. The uniform, spherically shaped solder 30 can increase the reliability in a connection between an electronic component and a circuit board.

The substrate 12 on which the electrode pad 14 is formed can be a flat base, and can be any one of a circuit board, a semiconductor wafer, and an electronic component. The post bump formed according to this embodiment can be formed on the electrode pad 14 of an electronic component or a circuit board, to be used in flip chip bonding. For example, it is possible to form the post bumps over the electrode pads 14 of an electronic component and then bond the electronic component with the post bumps to a circuit board, or conversely, to form the post bumps over the electrode pads 14 of the circuit board and then bond the component to the circuit board. Furthermore, as illustrated in FIG. 20, it is also possible bond the component with the circuit board after forming post bumps on both the electrode pads 14 of the component and on the electrode pads 14 of the circuit board. When manufacturing a wafer level package, the post bumps can be formed according to this embodiment over electrode pads 14 formed on the wafer.

The metal post 24 can be made of a conductive material, and in this particular embodiment, the metal post 24 can be made of copper, which can be attached to the electrode pad 14 in a stable manner. The height of the metal post 24 can be adjusted according to the height of the bump required for bonding. For example, for cases in which a small pitch between electrode pads 14 and a low bump height are required, the metal posts 24 can be given a low height. Conversely, for cases in which a high pitch between electrode pads 14 and a great bump height are required, the metal posts 24 can be given a great height. Similar to the previously described embodiment, the forming of the metal post 24 can include forming a seed layer and stacking a photosensitive film layer over the substrate on which the electrode pad 14 is formed, and then forming an aperture by opening up an area corresponding to the position of the electrode pad 14. Here, the height of the post bump and the height of the metal post 24 can be adjusted by changing the thickness of the photosensitive film layer stacked over the substrate.

When the aperture is opened, a metallic material can be filled in a part of the aperture to form the metal post 24.

The dome-shaped solder 30 can be reflowed to bond the substrate with an external device. The dome-shaped solder 30 can be formed by filling a solder 30 in a space defined by imaginary lines 32 that extend from the perimeter of the metal post 24 along the axial direction of the metal post 24. The dome-shaped solder 30 thus formed may not be formed over sides of the metal post 24 other than the top surface, making it possible to readily control the amount of solder 30 required for bonding.

If the solder 30 envelops the metal post 24 (see FIG. 7), it can be difficult to adjust the amounts of solder 30 formed on the metal posts 24 over numerous electrode pads 14, creating a risk of bridges occurring between adjacent bumps or of bonding defects caused by insufficient amounts of solder 30.

As described above, a method of forming the solder 30 over the metal post 24 in a dome shape that occupies a space defined by imaginary lines 32 extending from a perimeter of the metal post 24 along an axial direction of the metal post 24 can include the following procedures. After filling a metallic material and a solder 30 in order inside the aperture formed in the photosensitive film layer stacked over the substrate, the solder 30 can be heated for reflowing before having the photosensitive film layer removed, so that the solder 30 can be given a dome-like shape that occupies the space defined by imaginary lines 32 extending from a perimeter of the metal post 24 along an axial direction of the metal post 24 (e.g. the space formed by the remaining part of the aperture).

The solder 30 can be shaped as a dome, so as not to flow over the sides of the metal post 24 other than the top surface. Thus, the amount of solder 30 required for bonding may be controlled with greater ease.

The solder 30 can be any one selected from a group consisting of Sn—Pb solder, Sn—Ag solder, and Sn—Ag—Cu solder. Using Sn—Ag solder or Sn—Ag—Cu solder can reduce the use of lead.

FIGS. 17 to 19 illustrate various possible shapes for post bumps based on an embodiment of the invention. In cases where the pitch between multiple electrode pads 14 is small so that there is a risk of bridges forming between adjacent bumps, the solder 30 can be formed over the metal post 24 in the shape of a hemisphere using a small amount of solder 30, as illustrated in FIG. 17. Conversely, in cases where the pitch between electrode pads 14 is large so that there is a relatively lower risk of bridges forming between adjacent bumps, it is possible to form a pillar of solder 30 of a particular thickness over the metal post 24 and form the solder 30 hemisphere over the solder 30 pillar using a large amount of solder 30, as illustrated in FIG. 18. By thus adjusting the amount of solder 30 required for bonding, the amount of solder 30 used can be reduced, and bonding defects can be avoided.

FIG. 19 illustrates the case where the post bump is shaped as a rectangular prism. In cases where the metal post 24 formed over the electrode pad 14 is shaped as a rectangular prism, the solder 30 occupying the space defined by the imaginary lines 32 extending from a perimeter of each metal post 24 along an axial direction of the metal post 24 can be formed as a dome shape over the rectangular prism.

Other elements are substantially the same as those already described above.

FIG. 20 is a cross sectional view illustrating the bonding between post bumps according to the second disclosed embodiment of the invention. In FIG. 20, there are illustrated electrode pads 14, metal posts 24, solder 30, an electronic component 34, and a circuit board 36.

The post bumps formed according to this embodiment can be formed on the electrode pads 14 of either the electronic component 34 or the circuit board 36 to be used in flip chip bonding. For example, it is possible to form the post bumps over the electrode pads 14 of an electronic component and then bond the electronic component with the post bumps to the circuit board, or conversely, to form the post bumps over the electrode pads 14 of the circuit board and then bond the component to the circuit board. When manufacturing a wafer level package, the post bumps can be formed according to this embodiment over the electrode pads 14 of the wafer.

As illustrated in FIG. 20, it is also possible bond the electronic component 34 with the circuit board 36 after forming post bumps on the electrode pads 14 of both the electronic component 34 and the circuit board 36.

In cases where the electronic component 34 is flip-chip bonded to the circuit board 36, post bumps can be formed according to this embodiment over the electrode pads 14 of each of the electronic component 34 and the circuit board 36, and the electrode pads 14 of the circuit board 36 and the electrode pads 14 of the electronic component 34 can be aligned, after which the post bumps can be reflowed so that the respective bumps may bond to each other.

Certain embodiments of the invention make it possible to readily control the amount of solder 30 formed on the metal posts 24 and to proceed with the bonding using minimum amounts of solder 30. Thus, the forming of bridges between adjacent bonds may be prevented, and the reliability of the connections obtained from the bonding may be improved.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of forming a post bump, the method comprising:
forming a resist layer over a substrate, the substrate having an electrode pad formed thereon, and the resist layer having an aperture formed therein in correspondence to a position of the electrode pad;
forming a metal post by filling a part of the aperture with a metallic material;
filling a remaining part of the aperture with solder;
reflowing the solder by applying heat; and
removing the resist layer.

2. The method of claim 1, wherein the forming of the resist layer comprises:
stacking a photosensitive film layer over the substrate having the electrode pads formed thereon; and
forming the aperture by removing a portion of the photosensitive film layer by way of selective exposure and development such that an area corresponding to the position of the electrode pad is uncovered.

3. The method of claim 2, wherein the removing of the resist layer comprises:
removing the photosensitive film layer remaining on the substrate.

4. The method of claim 1, further comprising, before the forming of the resist layer:
forming a seed layer over the substrate by depositing a conductive material,
wherein the forming of the metal post comprises:
performing electroplating with the seed layer as an electrode.

5. The method of claim 4, further comprising, after the removing of the resist layer:
removing the seed layer exposed to the outside.

6. The method of claim 1, wherein the filling with the solder comprises:
forcing the solder into the remaining part of the aperture by squeegeeing.

7. The method of claim 2, wherein the photosensitive film layer is a dry film thermally resistant to the reflowing.

8. The method of claim 1, wherein the substrate is any one of a circuit board, a semiconductor wafer, and an electronic component.

9. The method of claim 1, wherein the solder is any one of a Sn—Pb solder, a Sn—Ag solder, and a Sn—Ag—Cu solder.

10. A post bump formed over an electrode pad of a substrate for electrically connecting to an external device, the post bump comprising:
a metal post formed over the electrode pad; and
a solder formed over the metal post and shaped as a dome, the dome occupying a space defined by imaginary lines extending from a perimeter of the metal post along an axial direction of the metal post.

11. The post bump of claim 10, wherein the substrate is any one of a circuit board, a semiconductor wafer, and an electronic component.

12. The post bump of claim 10, wherein the solder is any one of a Sn—Pb solder, a Sn—Ag solder, and a Sn—Ag—Cu solder.
